(19) United States
(12) Patent Application Publication
(10) Pub. No.: US 2013/0058391 A1
(43) Pub. Date: Mar. 7, 2013

(54) Timing Recovery Module and Timing Recovery Method

(71) Applicant: Wen-Sheng Hou, Hsinchu County (TW)

(72) Inventor: Wen-Sheng Hou, Hsinchu County (TW)

(21) Appl. No.: 13/224,306

(22) Filed: Sep. 1, 2011

(51) Int. Cl. H03H 7/30; H04L 27/01

(52) U.S. Cl. 375/232

(57) ABSTRACT

The present invention discloses a timing recovery module of a receiver of a communication system. The timing recovery module includes a timing error calculating unit, for calculating a timing error according to an output signal of an equalizer of the receiver; and a multiplexer, for receiving the timing error, a specific negative timing error and a specific positive timing error, and outputting one of the timing error, the specific negative timing error and the specific positive timing error as a timing adjustment value according to a main tape coefficient, a most negatively adjacent tape coefficient and a most positively adjacent tape coefficient of the equalizer.

### BACKGROUND OF THE INVENTION

1. Field of the Invention

The present invention relates to a timing recovery module and timing recovery method, and more particularly, to a timing recovery module and timing recovery method capable of performing joint timing recovery and channel equalization.

2. Description of the Prior Art

In a receiver of a wireless communication system, such as a Bluetooth (BT) communication system, since a timing recovery module and an equalizer for compensating channel effects operate separately, the timing recovery module and the equalizer may interfere with each other. In other words, other than compensating the channel effects, the equalizer also compensates sampling error, which interferes with operations of the timing recovery module. As a result, a timing error can not be recovered, which affects convergence and stability of the receiver.

For example, please refer to FIG. 1A, which is a schematic diagram of an equalizer 100 of a Gaussian Frequency-Shift Keying (GFSK) receiver 10 of a BT communication system. As shown in FIG. 1A, the GFSK receiver 10 includes the equalizer 100 and a discriminator 102. The discriminator 102 demodulates a GFSK signal into a Binary Phase Key Shifting (BPSK) input signal y(n) for the equalizer 100. The equalizer 100 is a decision feedback equalizer (DFE) for reducing channel effects, and includes a feed forward filter W₁, a feedback filter W₂, an adder 104 and a decision device 106.

In detail, the feed forward filter W₁ reduces pre-echo and post-echo with tap coefficients W₁(n) to generate an output signal c′(n), while the feedback filter W₂ reduce post-echo with tap coefficients W₂(n) to generate an output signal d′(n). The adder 104 adds the output signal c′(n) and the output signal d′(n) to generate a signal b′(n), and the decision device 106 performs hard decision on the signal b′(n) to generate an output signal b(n). The tap coefficients W₁(n) of the feed forward filter W₁ and the tap coefficients W₂(n) of the feedback filter W₂ can be derived and updated by using adaptive least mean square (LMS) algorithm, which can be represented by equations as follows:

W₁(n+1)=W₁(n)+u₁·Y(n)·(b(n)−b′(n))

W₂(n+1)=W₂(n)+u₂·B(n)·(b(n)·b′(n))

where

Y(n)=[Λ,y(n+1),y(n),y(n−1),Λ]

B(n)=[b(n−1),b(n−2),Λ]

W₁(n)=[Λ,w₁_{_{—}}₋₁(n),w₁_{_{—}}₀(n),w₁_{_{—}}₁(n),Λ]

W₂(n)=[w₂_{_{—}}₀(n)w₂_{_{—}}₁(n),Λ]

where u₁ and u₂ represent step sizes of the LMS algorithm. Detail operations of the decision feedback equalizer 100 are known by those skilled in the art.

On the other hand, please refer to FIG. 1B, which is a schematic diagram of a timing recovery module 108 of the GFSK receiver 10 of the BT communication system shown in FIG. 1A. As shown in FIG. 1B, the GFSK receiver 10 further includes the timing recovery module 108 for timing recovery. The timing recovery module 108 includes a timing error calculating unit 110, a loop filter 112, a numerically-controlled oscillator (NCO) 114 and an interpolator 116.

In detail, the timing error calculating unit 110 utilizes a Mueller Muller algorithm to calculate a timing error e(n) according to the output signal b(n) and the signal b′(n) , which can be expressed as follows:

e(n)=b(n−1)b′(n)−b(n)b′(n−1)

The loop filter 112 is a first-order filter, i.e. uₜ, and generates a compensation signal according to the timing error e(n), and thus the NCO 114 can generate a compensated sampling clock signal SCS according to the compensation signal, to compensate the timing error e(n). As a result, the interpolator 116 can sample an analog signal according to the compensated sampling clock signal SCS, to recover the timing error e(n) in the input signal y(n).

However, since both training signals of the equalizer 100 and the timing recovery module 108 are outputted by the equalizer 100 which compensates the channel effects as well as sampling error, the equalizer 100 and the timing recovery module 108 may interfere with each other, which affects convergence and stability of the receiver 10.

In another example, please refer to FIG. 2A, which is a schematic diagram of an equalizer 200 of a Differential Phase Shift Keying (DPSK) receiver 20 of a BT communication system, wherein elements have similar functions with those shown in FIG. 1A are denoted by same symbols. As shown in FIG. 2A, a main difference between the equalizer 200 and the equalizer 100 is that the equalizer 200 is a linear equalizer for reducing channel effects, and only includes a feed forward filter W₁, for reducing pre-echo and post-echo with tap coefficients W₁(n). The tap coefficients W₁(n) can be derived and updated by using adaptive constant modulus algorithm (CMA) algorithm, which can be represented by equations as follows:

c′(n)=Y(n)W₁(n)

W₁(n+1)=W₁(n)+u₁Y^{H}(n)c′(n)(Rₚ−|c′(n)|²)

where Rₚ is received power and H is Hermitian transposition. Detail operations of the decision feedback equalizer 100 are known by those skilled in the art.

On the other hand, please refer to FIG. 2B, which is a schematic diagram of a timing recovery module 202 of the DPSK receiver 20 of the BT communication system shown in FIG. 2A, wherein elements have similar functions with those shown in FIG. 2B are denoted by same symbols. As shown in FIG. 2B, a main difference between the DPSK receiver 20 and the GFSK receiver 10 is that the DPSK receiver 20 further includes a differential demodulation 204 and a decision device 206. The differential demodulation 204 demodulates the output signal c′(n) and includes a delay unit 208, a conjugation unit 210 and an adder 212. The delay unit 208 delays the output signal c′(n) by one symbol, the conjugation unit 210 performs an conjugation operation on the delayed signal and the adder 212 adds the output signal c′(n) with the conjugated signal, to generate a signal c″(n). The decision device 206 performs hard decision on the signal c″(n) to generate an output signal c(n). Since the signal c″(n) is demodulated DPSK signal which is a complex signal and thus only image components are symmetric, the timing error calculating unit 110 utilizes a Mueller Muller algorithm to calculate the timing error e(n) according to only image components of the output signal c(n) and the signal c″(n), which can be expressed as follows:

e(n)=Im{c(n−1)}·Im{c″(n)}−Im{c(n)}·Im{c″(n−1)}

The loop filter 112 is a first-order filter, i.e. uₜ, and generates a compensation signal according to the timing error e(n), and thus the NCO 114 can generate a compensated sampling clock signal SCS according to the compensation signal, to compensate the timing error e(n). As a result, the interpolator 116 can sample an analog signal according to the compensated sampling clock signal SCS, to recover the timing error e(n) in the input signal y(n).

However, since both training signals of the equalizer 200 and the timing recovery module 202 are outputted by the equalizer 200 which compensates the channel effects as well as sampling error, the equalizer 200 and the timing recovery module 202 may interfere with each other, which affects convergence and stability of the receiver 20.

In order to resolve the above problem, the prior art limits magnitudes of the tap coefficients W₁(n) excluding a main tape coefficient W₁_{_{—}}₀. In detail, please refer to FIG. 3A and 3B, which are schematic diagrams of the tap coefficients W₁(n) of the feed forward filter W₁ shown in FIG. 1A and 2A without and with limited magnitudes when there is a great timing error, respectively. As shown in FIG. 3A, when there is a great timing error and the magnitudes of the tap coefficients W₁(n) are not limited, a most negatively adjacent tape coefficient W₁_{_{—}}₋₁ may become greater than the main tape coefficient W₁_{_{—}}₀, e.g. 1>0.1. As shown in FIG. 3B, when there is a great timing error and the magnitudes of the tap coefficients W₁(n) are limited, the most negatively adjacent tape coefficient W₁_{_{—}}₋₁ to the main tape coefficient W₁_{_{—}}₀ is limited to the limited magnitude instead, e.g. 0.5, such that the feed forward filter W₁ has less capability for compensating timing error and thus timing recovery is mainly performed by the timing recovery module.

However, since magnitudes of the tap coefficients of the equalizer are limited, the equalizer also has less capability for compensating channel effects. Thus, there is a need for improvement over the prior art.

### SUMMARY OF THE INVENTION

It is therefore an objective of the present invention to provide a timing recovery module and timing recovery method, and more particularly, to a timing recovery module and timing recovery method capable of performing Joint Timing recovery and channel equalization.

The present invention discloses a timing recovery module of a receiver of a communication system. The timing recovery module includes a timing error calculating unit, for calculating a timing error according to an output signal of an equalizer of the receiver; and a multiplexer, for receiving the timing error, a specific negative timing error and a specific positive timing error, and outputting one of the timing error, the specific negative timing error and the specific positive timing error as a timing adjustment value according to a main tape coefficient, a most negatively adjacent tape coefficient and a most positively adjacent tape coefficient of the equalizer.

The present invention further discloses a timing recovery method for a receiver of a communication system. The timing recovery method includes steps of calculating a timing error according to an output signal of an equalizer of the receiver; and outputting one of the timing error, a specific negative timing error and a specific positive timing error as a timing adjustment value according to a main tape coefficient, a most negatively adjacent tape coefficient and a most positively adjacent tape coefficient of the equalizer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of an equalizer of a Gaussian Frequency-Shift Keying receiver of a Bluetooth communication system.

FIG. 1B is a schematic diagram of a timing recovery module of the Gaussian Frequency-Shift Keying receiver of the BT communication system shown in FIG. 1A.

FIG. 2A is a schematic diagram of an equalizer of a Differential Phase Shift Keying receiver 20 of a BT communication system.

FIG. 2B is a schematic diagram of a timing recovery module of the Differential Phase Shift Keying receiver of the BT communication system shown in FIG. 2A.

FIG. 3A and 3B are schematic diagrams of tap coefficients of a feed forward filter shown in FIG. 1A and 2A without and with limited magnitudes when there is a great timing error, respectively.

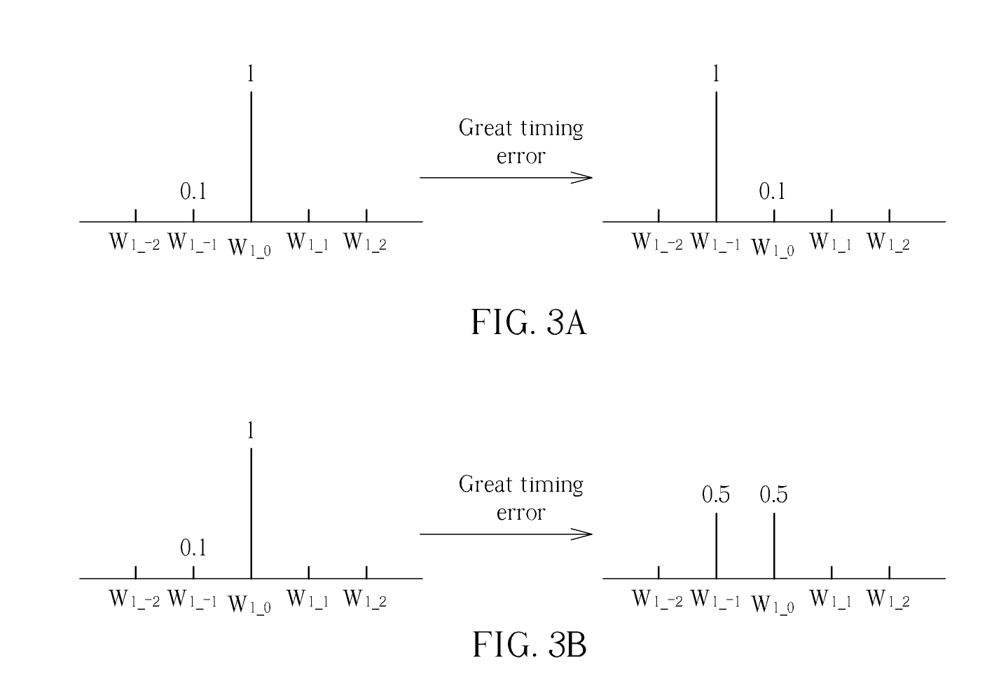

FIG. 4 is a schematic diagram of a timing recovery module of a receiver of a communication system according to an embodiment of the present invention.

FIG. 5A and FIG. 5B are schematic diagrams of tap coefficients of a feed forward filter shown in FIG. 4 when there is a great negative timing error and a great positive timing error, respectively.

FIG. 6 is a schematic diagram of the timing recovery module shown in FIG. 4 applied in another receiver according to another embodiment of the present invention.

FIG. 7 is a schematic diagram of a timing recovery process according to an embodiment of the present invention.

### DETAILED DESCRIPTION

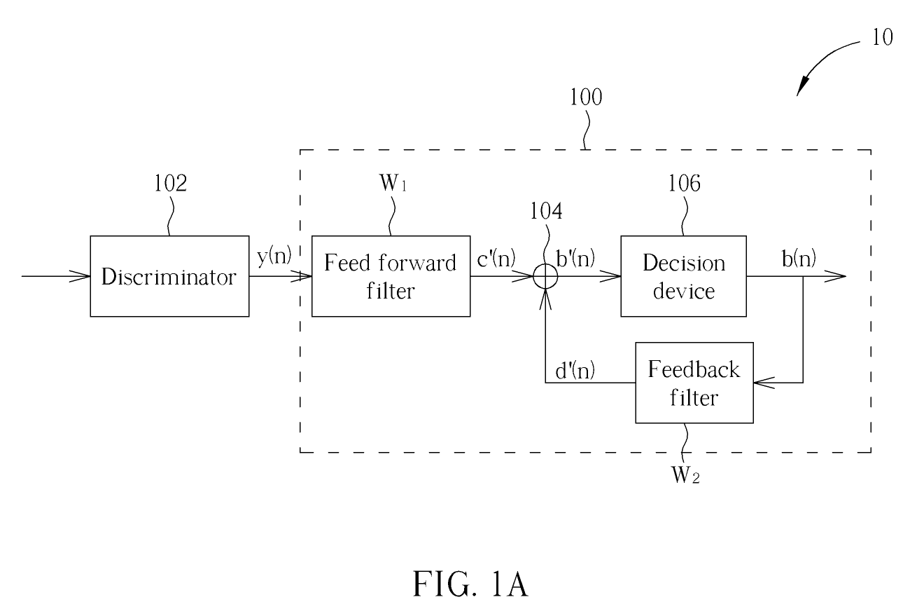

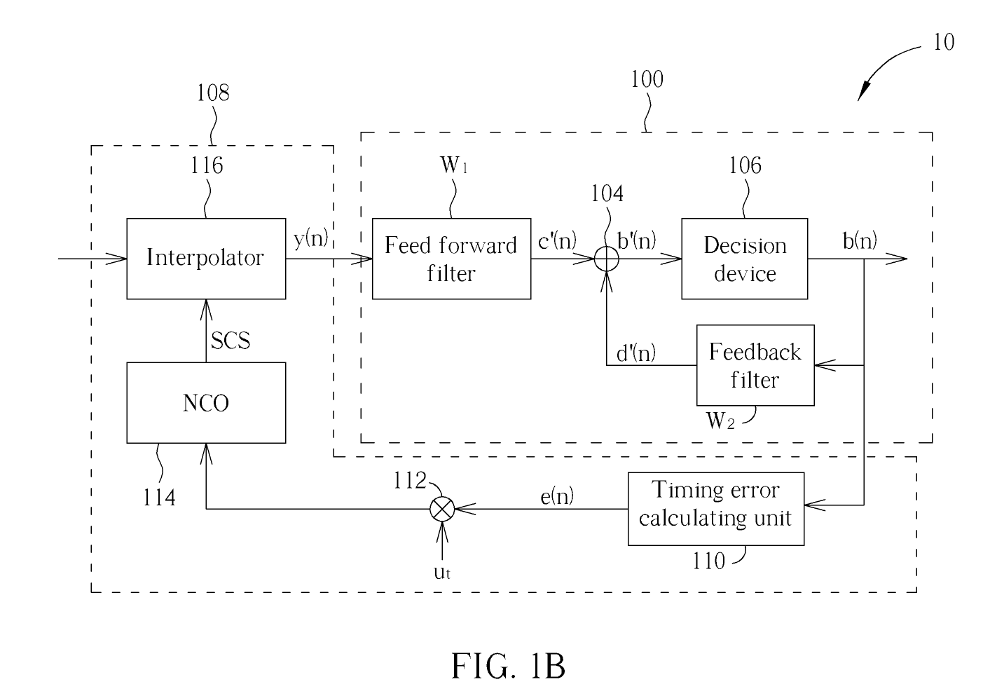

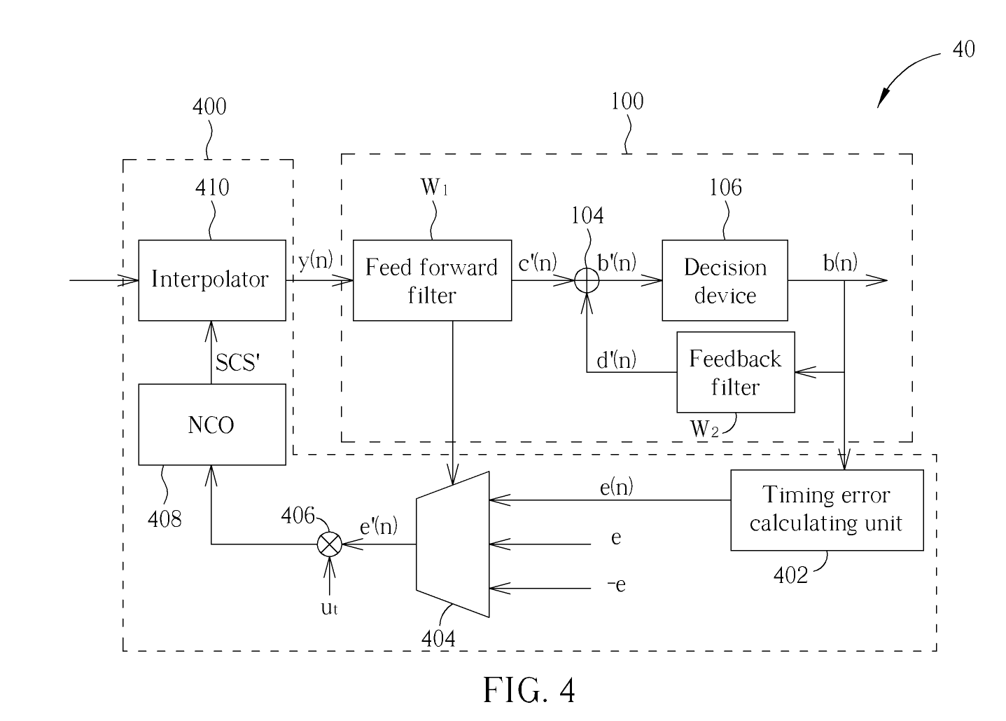

Please refer to FIG. 4, which is a schematic diagram of a timing recovery module 400 of a receiver 40 of a communication system according to an embodiment of the present invention. The receiver 40 is preferably a Gaussian Frequency-Shift Keying (GFSK) receiver of a Bluetooth (BT) communication system, and is not limited to this. Elements of the receiver 40 have similar functions with those shown in FIG. 1B are denoted by same symbols. As shown in FIG. 4, the timing recovery module 400 includes a timing error calculating unit 402, a multiplexer 404, a loop filter 406, a numerically-controlled oscillator (NCO) 408 and an interpolator 410, and a main difference between the timing recovery module 400 and the timing recovery module 108 is that the timing recovery module 400 determines a timing adjustment value e′(n) for timing compensation according to the tap coefficients W₁(n) of the feed forward filter W₁. As a result, the receiver 40 performs joint timing recovery and channel equalization by determining the timing adjustment value e′(n) according to the tap coefficients W₁(n).

In detail, the timing error calculating unit 402 calculates the timing error e(n) according to the output signal b(n) and the signal b′(n) of the equalizer 100 of the receiver 40. The multiplexer 404 receives the timing error e(n), a specific negative timing error −e and a specific positive timing error e at input terminals, and outputs one of the timing error e(n), the specific negative timing error −e and the specific positive timing error e as the timing adjustment value e′(n) according to the main tape coefficient W₁_{_{—}}₀, the most negatively adjacent tape coefficient W₁_{_{—}}₋₁ and a most positively adjacent tape coefficient W₁_{_{—}}₁ among the tap coefficients W₁(n) of the equalizer 100. The loop filter 406 is a first-order filter, i.e. uₜ, and generates a compensation signal according to the timing adjustment value e′(n), and thus the NCO 408 can generate a compensated sampling clock signal SCS′ according to the compensation signal. As a result, the interpolator 410 can sample the analog signal according to the compensated sampling clock signal SCS′ which is compensated by the timing adjustment value e′(n).

Specifically, if the most negatively adjacent tape coefficient W₁_{_{—}}₋₁ is greater than a threshold k times the main tape coefficient W₁_{_{—}}₀, the multiplexer 404 outputs the specific negative timing error −e as the timing adjustment value e′(n). If the most positively adjacent tape coefficient W₁_{_{—}}₁ is greater than the threshold k times the main tape coefficient W₁_{_{—}}₀, the multiplexer 404 outputs the specific positively timing error e as the timing adjustment value e′(n). If the most positively adjacent tape coefficient W₁_{_{—}}₁ and the most negatively adjacent tape coefficient W₁_{_{—}}₋₁ are both less than the threshold k times the main tape coefficient W₁_{_{—}}₀, the multiplexer 404 outputs the timing error e(n) calculated by the timing error calculating unit 402 as the timing adjustment value e′(n), the above descriptions can be expressed as follows:

if |w₁_{_{—}}₋₁(n)|>k|w₁_{_{—}}₀(n)|

e′(n)=−e

else if |w₁_{_{—}}₁(n)|>k|w₁_{_{—}}₀(n)|

e′(n)=e

else

e′(n)=e(n)

where 0<k<1.

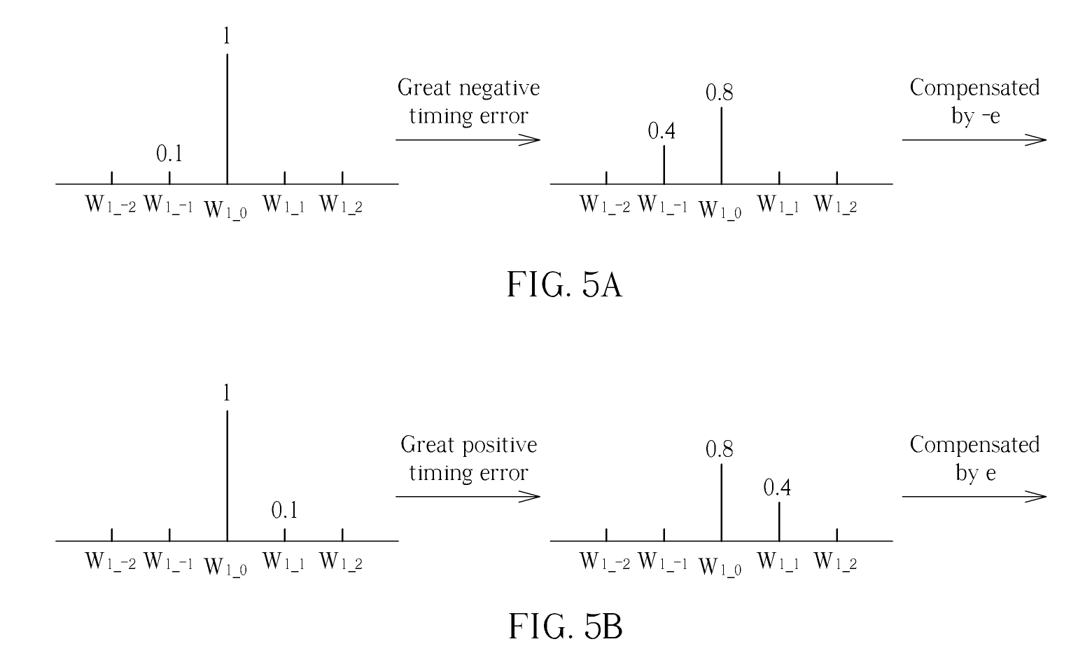

In other words, please refer to FIG. 5A and FIG. 5B, which are schematic diagrams of the tap coefficients W₁ (n) of the feed forward filter W₁ shown in FIG. 4 when there is a great negative timing error and a great positive timing error, respectively. As shown in FIG. 5A, during a signal training process, when there is a great negative timing error, the most negatively adjacent tape coefficient W₁_{_{—}}₋₁ may gradually become greater to exceed the decreased main tape coefficient W₁_{_{—}}₀. When the most negatively adjacent tape coefficient W₁_{_{—}}₋₁ is greater than the threshold k times the main tape coefficient W₁_{_{—}}₀, e.g. k=0.4/0.8=0.5, the multiplexer 404 outputs the specific negative timing error −e as the timing adjustment value e′(n) for timing compensation, and thus the compensated sampling clock signal SCS′ can be compensated with the specific negative timing error −e, such that a position of the input signal y(n) with a strongest signal can be modified to the position of the main tape coefficient W₁_{_{—}}₀.

Similarly, as shown in FIG. 5B, during a signal training process, when there is a great positive timing error, the most positively adjacent tape coefficient W₁_{_{—}}₁ may gradually become greater to exceed the decreased main tape coefficient W₁_{_{—}}₀. When the most positively adjacent tape coefficient W₁_{_{—}}₁ is greater than the threshold k times the main tape coefficient W₁_{_{—}}₀, e.g. k=0.4/0.8=0.5, the multiplexer 404 outputs the specific positive timing error e as the timing adjustment value e′(n) for timing compensation, and thus the compensated sampling clock signal SCS′ can be compensated with the specific positive timing error e, such that a position of the input signal y(n) with a strongest signal can be modified to the position of the main tape coefficient W₁_{_{—}}₀.

As a result, when there is a great timing error, the compensated sampling clock signal SCS′ can be compensated with a specific timing error rather than the timing error e (n) calculated by the timing error calculating unit 402, so as to compulsively modify the position of the input signal y(n) with the strongest signal back to the position of the main tape coefficient W₁_{_{—}}₀ for timing recovery.

Noticeably, the spirit of the present invention is to determining the timing adjustment value e′(n) for timing compensation according to the main tape coefficient W₁_{_{—}}₀, the most negatively adjacent tape coefficient W₁_{_{—}}₋₁ and a most positively adjacent tape coefficient W₁_{_{—}}₁ of the equalizer 100, to perform joint timing recovery and channel equalization, so as to compulsively modify the position of the input signal y(n) with the strongest signal back to the position of the main tape coefficient W₁_{_{—}}₀ when there is a great timing error. Those skilled in the art should make modification or alterations accordingly. For example, the timing error calculating unit 402 preferably utilizes a Mueller Muller algorithm to calculate the timing error e(n), but can utilize other algorithms as well.

Besides, in the above embodiment, the timing recovery module 400 is applied in the GFSK receiver 40 shown in FIG. 4, where the equalizer 100 includes the feed forward filter W1, the feedback filter W₂, the adder 104 and the decision device 106, and the feed forward filter W1 reduces pre-echo and post-echo according to the tap coefficients W₁(n) comprising the main tape coefficient W₁_{_{—}}₀, the most negatively adjacent tape coefficient W₁_{_{—}}₋₁ and the most positively adjacent tape coefficient W₁_{_{—}}₁.

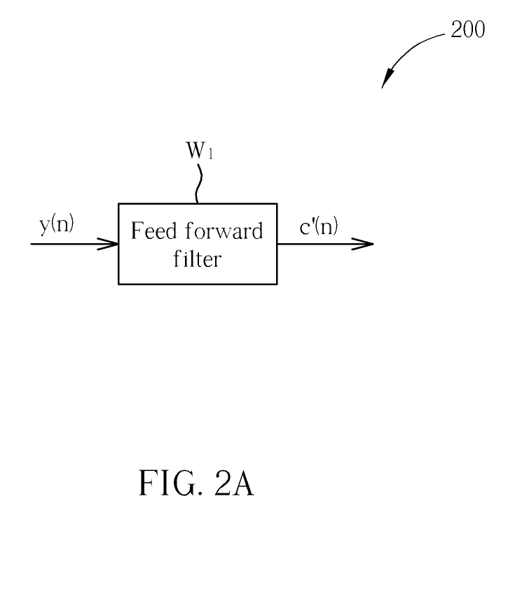

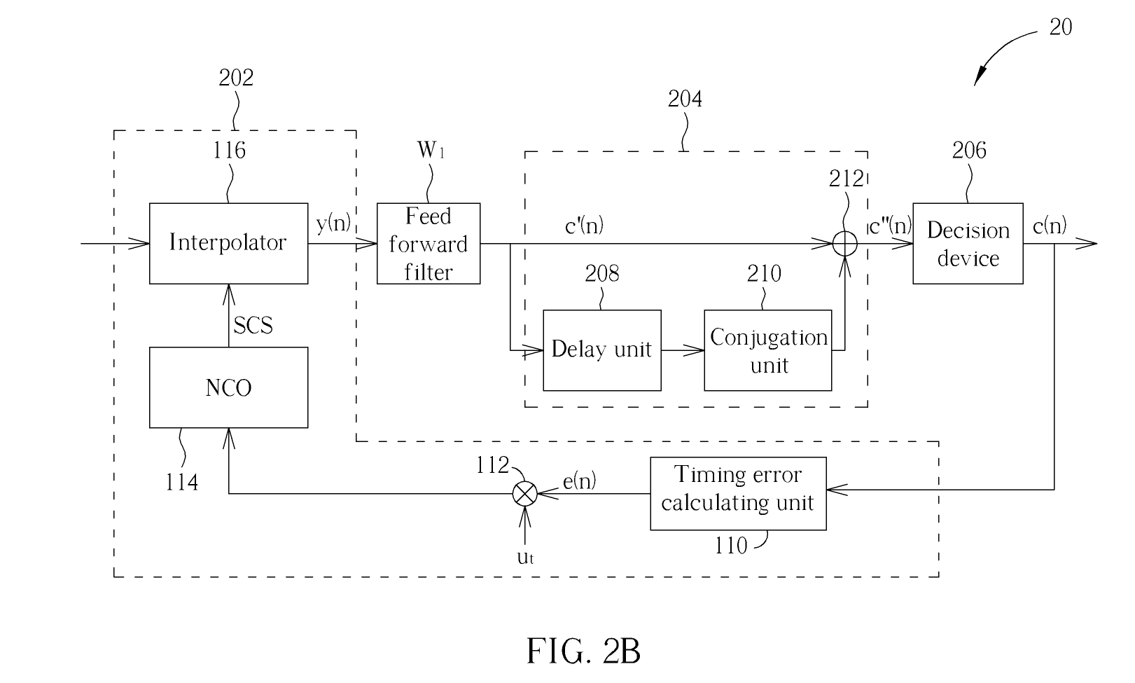

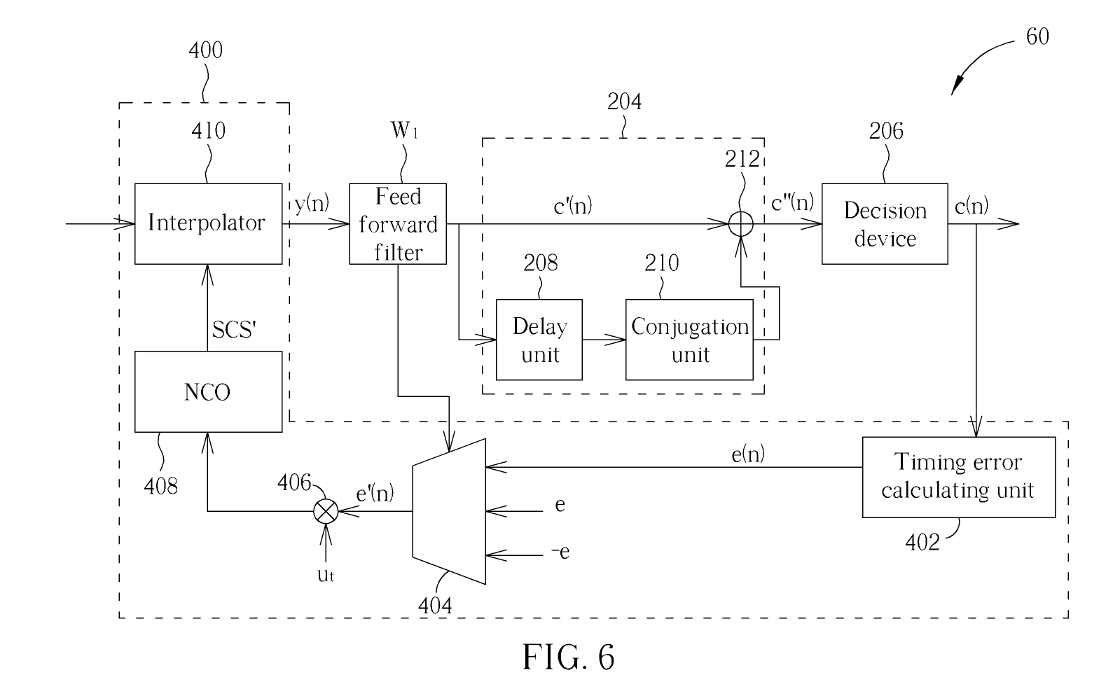

However, the timing recovery module 400 can also be applied in other receivers comprising an equalizer or other communication systems as long as corresponding modifications are made. For example, the timing recovery module 400 can also be applied in a Differential Phase Shift Keying (DPSK) receiver 50 of a BT communication system as shown in FIG. 6, where elements of the receiver 50 have similar functions with those shown in FIG. 2B are denoted by same symbols. Under such a configuration, the equalizer 200 only includes the feed forward filter W₁, for reducing pre-echo and post-echo according to the tap coefficients W₁(n) comprising the main tape coefficient W₁_{_{—}}₀, the most negatively adjacent tape coefficient W₁_{_{—}}₋₁ and the most positively adjacent tape coefficient W₁_{_{—}}₁; The receiver 50 includes the differential demodulation 204 and the decision device 206 as those shown in FIG. 2B. The timing error calculating unit 402 is corresponding modified to calculate the timing error e(n) according to only image components of the output signal c(n) and the signal c″(n) which are derived from the output signal c′(n) of the equalizer 200.

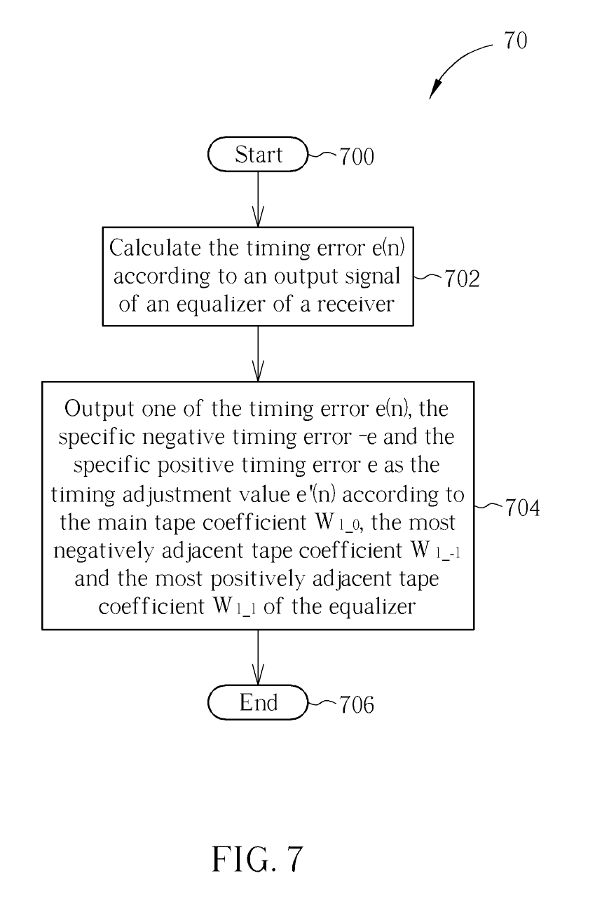

Operations of the timing recovery module 400 can be summarized in to a timing recovery process 70 as shown in FIG. 7. The timing recovery process 70 includes following steps:

Step 700: Start.

Step 702: Calculate the timing error e(n) according to an output signal of an equalizer of a receiver.

Step 704: Output one of the timing error e(n), the specific negative timing error −e and the specific positive timing error e as the timing adjustment value e′(n) according to the main tape coefficient W₁_{_{—}}₀, the most negatively adjacent tape coefficient W₁_{_{—}}₋₁ and the most positively adjacent tape coefficient W₁_{_{—}}₁ of the equalizer.

Step 706: End.

Details of the timing recovery process 70 can be derived by referring to the above descriptions.

In the prior, in order to prevent the equalizer from interfering with timing recovery operations of the timing recovery module, magnitudes of the tap coefficients are limited, which also limits capability of the equalizer to compensate channel effects. In comparison, the present invention determines the timing adjustment value e′(n) for timing compensation according to the main tape coefficient W₁_{_{—}}₀, the most negatively adjacent tape coefficient W₁_{_{—}}₋₁ and a most positively adjacent tape coefficient W₁_{_{—}}₁ of the equalizer 100, to perform joint timing recovery and channel equalization, so as to compulsively modify the position of the input signal y(n) with the strongest signal back to the position of the main tape coefficient W₁_{_{—}}₀ when there is a great timing error.

To sum up, the present invention can perform joint timing recovery and channel equalization by determining the timing adjustment value e′(n) according to the tap coefficients W₁(n).

Those skilled in the art will readily observe that numerous modifications and alterations of the device and method may be made while retaining the teachings of the invention.

What is claimed is:

1. A timing recovery module of a receiver of a communication system,
the timing recovery module comprising:
a timing error calculating unit, for calculating a timing error according to an output signal of an equalizer of the receiver; and
a multiplexer, for receiving the timing error, a specific negative timing error and a specific positive timing error, and outputting one of the timing error, the specific negative timing error and the specific positive timing error as a timing adjustment value according to a main tape coefficient, a most negatively adjacent tape coefficient and a most positively adjacent tape coefficient of the equalizer.

2. The timing recovery module of claim 1, wherein the timing recovery module further comprises:
a loop filter, for generating a compensation signal according to the timing adjustment value; and
a numerically-controlled oscillator (NCO), for generating a compensated sampling clock signal according to the compensation signal.

3. The timing recovery module of claim 2, wherein the timing recovery module further comprises an interpolator for sampling an analog signal according to the compensated sampling clock signal.

4. The timing recovery module of claim 1, wherein the multiplexer outputs the specific negative timing error as the timing adjustment value if the most negatively adjacent tape coefficient is greater than a threshold times the main tape coefficient.

5. The timing recovery module of claim 1, wherein the multiplexer outputs the specific positive timing error as the timing adjustment value if the most positively adjacent tape coefficient is greater than a threshold times the main tape coefficient.

6. The timing recovery module of claim 1, wherein the multiplexer outputs the timing error as the timing adjustment value if the most positively adjacent tape coefficient and the most negatively adjacent tape coefficient are both less than a threshold times the main tape coefficient.

7. The timing recovery module of claim 1, wherein the timing error calculating unit utilizes a Mueller Muller algorithm to calculate the timing error.

8. The timing recovery module of claim 1, wherein the equalizer comprises a feed forward filter, for reducing pre-echo and post-echo according to a plurality of tape coefficients comprising the main tape coefficient, the most negatively adjacent tape coefficient and the most positively adjacent tape coefficient.

9. The timing recovery module of claim 1, wherein the equalizer further comprises a feedback filter, an adder and a decision device.

10. The timing recovery module of claim 1, wherein the receiver further comprises a differential demodulation and a decision device.

11. A timing recovery method for a receiver of a communication system, the timing recovery method comprising:
calculating a timing error according to an output signal of an equalizer of the receiver; and
outputting one of the timing error, a specific negative timing error and a specific positive timing error as a timing adjustment value according to a main tape coefficient, a most negatively adjacent tape coefficient and a most positively adjacent tape coefficient of the equalizer.

12. The timing recovery method of claim 11 further comprising:
generating a compensated sampling clock signal according to the timing adjustment value.

13. The timing recovery module of claim 12 further comprising:
sampling an analog signal according to the compensated sampling clock signal.

14. The timing recovery method of claim 11, wherein the step of outputting one of the timing error, the specific negative timing error and the specific positive timing error as the timing adjustment value according to the main tape coefficient, the most negatively adjacent tape coefficient and the most positively adjacent tape coefficient of the equalizer comprises:
outputting the specific negative timing error as the timing adjustment value if the most negatively adjacent tape coefficient is greater than a threshold times the main tape coefficient.

15. The timing recovery method of claim 11, wherein the step of outputting one of the timing error, the specific negative timing error and the specific positive timing error as the timing adjustment value according to the main tape coefficient, the most negatively adjacent tape coefficient and the most positively adjacent tape coefficient of the equalizer comprises:
outputting the specific positive timing error as the timing adjustment value if the most positively adjacent tape coefficient is greater than a threshold times the main tape coefficient.

16. The timing recovery method of claim 11, wherein the step of outputting one of the timing error, the specific negative timing error and the specific positive timing error as the timing adjustment value according to the main tape coefficient, the most negatively adjacent tape coefficient and the most positively adjacent tape coefficient of the equalizer comprises:
outputting the timing error as the timing adjustment value if the most positively adjacent tape coefficient and the most negatively adjacent tape coefficient are both less than a threshold times the main tape coefficient.

17. The timing recovery method of claim 11, wherein the step of calculating the timing error according to the equalized signal generated by the equalizer of the receiver comprises:
utilizing a Mueller Muller algorithm to calculate the timing error.

18. The timing recovery method of claim 11 further comprising:
reducing pre-echo and post-echo according to a plurality of tape coefficients comprising the main tape coefficient, the most negatively adjacent tape coefficient and the most positively adjacent tape coefficient.
